(19) United States
(12) Patent Application Publication
(10) Pub. No.: US 2026/0223571 A1
(43) Pub. Date: Jul. 30, 2026

(54) DISPLAY DEVICE INCLUDING FILLING, ELECTRONIC DEVICE INCLUDING THE DISPLAY DEVICE, AND METHOD OF MANUFACTURING THE DISPLAY DEVICE

(71) Applicant: SAMSUNG DISPLAY CO., LTD., YONGIN-SI (KR)

(72) Inventor: JUNMO IM, Yongin-si (KR)

(21) Appl. No.: 19/383,851

(22) Filed: Nov. 10, 2025

(30) Foreign Application Priority Data
Jan. 24, 2025 (KR) 10-2025-0011280

(51) Int. Cl. H10K 59/80; H10K 59/12

(52) U.S. Cl. CPC H10K 59/873; H10K 59/1201; H10K 59/879

(57) ABSTRACT

A display device includes a first substrate, a second substrate disposed on the first substrate, and a filling layer disposed between the first substrate and the second substrate. The first substrate includes a first base layer, a display element layer including a light-emitting element disposed on the first base layer, a light control layer including a division pattern disposed on the display element layer and having an opening in the light control layer, a light control part disposed in the opening, and a functional layer disposed on the light control part. The functional layer includes a barrier layer, a refraction compensation layer disposed on the barrier layer, and a thin film layer disposed on the refraction compensation layer, and wherein the thin film layer has a hydrophobic surface facing the second substrate.

### CROSS-REFERENCE TO RELATED APPLICATIONS

This U.S. non-provisional patent application claims priority under 35 U.S.C. § 119 to Korean Patent Application No. 10-2025-0011280, filed on January 24, 2025, the entire disclosure of which is incorporated by reference.

### TECHNICAL FIELD

Embodiment of the present disclosure relate to a display device and, more particularly, to display device including a filling, an electronic device including the display device, and method of manufacturing the display device.

### DISCUSSION OF THE RELATED ART

Display devices provide images that are viewable by a user. There are various examples of display devices such as a television, a computer monitor, a mobile phone, and an electronic billboard, where these display devices may be used in various applications. In a manufacturing process of a display device, two substrates may be bonded together to form a laminated structure that are parts of the display device. However, during the manufacturing process, uneven spreading of filler material between the substrates may result in visual defects or optical non-uniformities.

### SUMMARY

The present disclosure provides a display device which is manufactured by bonding two substrates, where a visible stain defect on the display device is prevented by uniformly spreading filling material between the two substrates.

An embodiment of the inventive concept provides a display device including a first substrate including a first base layer, a display element layer including a light-emitting element disposed on the first base layer, a light control layer including a division pattern disposed on the display element layer and having an opening in the light control layer, a light control part disposed in the opening, and a functional layer disposed on the light control part. The display device further includes a second substrate disposed on the first substrate and including a second base layer, and a filling layer disposed between the first substrate and the second substrate.

In an embodiment, the functional layer may include a barrier layer, a refraction compensation layer disposed on the barrier layer, and a thin film layer disposed on the refraction compensation layer and having a hydrophobic surface facing the second substrate.

In an embodiment, the barrier layer may include silicon nitride, and the refraction compensation layer may include silicon oxide, and the thin film layer may include aluminum oxide.

In an embodiment, the barrier layer and the refraction compensation layer may include at least one of polyimide, polycarbonate, polyethylene, or polyvinyl carbonate.

In an embodiment, the thin film layer may be directly disposed on the refraction compensation layer, and the refraction compensation layer may be directly disposed on the barrier layer.

In an embodiment, the refraction compensation layer may have a refractive index of about 1.68 to about 1.8, inclusive.

In an embodiment, the thin film layer may be formed using atomic layer deposition.

In an embodiment, the thin film layer may have a thickness of about 0.01 μm to about 2 μm, inclusive.

In an embodiment, the light control part includes a first light control part, a second light control part, and a third light control part, and at least one of the first light control part, the second light control part, and the third light control part includes a quantum dot.

In an embodiment, the filling layer may include water or alcohol and the filling layer may be directly disposed on the thin film layer.

In an embodiment, the thin film layer may include silicon oxide or silicon nitride and the thin film layer may include protrusions protruding toward the second substrate.

In an embodiment, the second substrate may further include a color filter layer disposed under the second base layer.

In an embodiment of the inventive concept, a method of manufacturing a display device includes providing a first preliminary substrate. The first preliminary substrate may include a base layer, a display element layer including a light-emitting element disposed on the base layer, a light control layer including a division pattern disposed on the display element layer and having an opening in the light control layer, and a light control part disposed in the opening. The method may further include forming a barrier layer on the light control part, forming a refraction compensation layer on the barrier layer, providing a first substrate by forming a thin film layer including a hydrophobic material on the refraction compensation layer to obtain a first substrate, providing a second substrate including a second base layer, depositing filling material on a surface of the second substrate, and bonding the first substrate to the second substrate.

In an embodiment, forming the thin film layer may further include depositing aluminum oxide on the refraction compensation layer using atomic layer deposition.

In an embodiment, the thin film layer may be formed to a thickness of about 0.01 μm to about 2 μm, inclusive.

In an embodiment, forming the thin film layer may include forming a preliminary thin film layer including silicon oxide or silicon nitride on the refraction compensation layer using chemical vapor deposition, and forming protrusions on the preliminary thin film layer using a plasma treatment process.

In an embodiment, depositing the filling material may include ejecting the filling material onto the first preliminary substrate such that the filling material are spaced apart from each other at a predetermined interval.

In an embodiment, bonding the first and second substrates may include positioning the thin film layer to contact the filling material.

In an embodiment, the filling material may include a hydrophilic material, and the thin film layer may be repulsive to the filling material.

In an embodiment of the inventive concept, an electronic device includes a display device, a window disposed on the display device, a case housing the display device, and an electronic module electrically connected to the display device. The display device may include a first substrate, a second substrate disposed on the first substrate and including a second base layer, and a filling layer disposed between the first substrate and the second substrate. The first substrate may include a first base layer, a display element layer including a light-emitting element disposed on the first base layer, a light control layer including a division pattern disposed on the display element layer and having an opening in the light control layer, a light control part disposed in the opening, and a functional layer disposed on the light control part. The functional layer may include a barrier layer, a refraction compensation layer disposed on the barrier layer, and a thin film layer disposed on the refraction compensation layer and having a hydrophobic surface facing the second substrate.

In an embodiment, the barrier layer may include silicon nitride, and the refraction compensation layer may include silicon oxide, and the thin film layer may include aluminum oxide and may be in direct contact with the filling layer.

### BRIEF DESCRIPTION OF THE FIGURES

The accompanying drawings are included to provide a further understanding of the inventive concept. The drawings illustrate embodiments of the inventive concept and, together with the description, serve to explain principles of the inventive concept. In the drawings:

FIG. 1 is a block diagram of an electronic device according to an embodiment of the present disclosure;

FIG. 2 illustrates schematic views of an electronic device according to various embodiments of the present disclosure;

FIG. 3 is a perspective view of an electronic device according to an embodiment of the present disclosure;

FIG. 4 is an exploded perspective view of an electronic device according to an embodiment the present disclosure;

FIG. 5 is a cross-sectional view of a display device according to an embodiment of the present disclosure;

FIG. 6 is an enlarged view of a portion of a display device according to an embodiment of the present disclosure;

FIG. 7 is a cross-sectional view illustrating a portion of a display device according to an embodiment of the present disclosure;

FIG. 8 is a block diagram illustrating a method of manufacturing a display device according to an embodiment of the present disclosure;

FIGS. 9, 10, 11, 12, 13, 14, 15 , 16, 17, 18 and 19 are diagrams illustrating respective steps of the method for manufacturing a display device according to an embodiment of the present disclosure; and

FIGS. 20 and 21 are diagrams illustrating respective steps of a method for manufacturing a display device according to an embodiment of the present disclosure.

### DETAILED DESCRIPTION

In the present disclosure, various modifications may be made and various forms may be applied, and specific embodiments are illustrated in the drawings and described in detail. However, this is not necessarily intended to limit the inventive concept to a specific disclosure form, it should be understood to include all changes, equivalents, and substitutes included in the spirit and scope of the inventive concept.

In the present disclosure, it will be understood that when an element (or a region, a layer, a portion, or the like) is referred to as being "on", "connected to" or "coupled to" another element, the element may be directly disposed on, connected to, or coupled to the other element, or one or more elements may be disposed therebetween. For example, intervening regions, layers, or portions may be present between the regions, layers, or portions, respectively

Like reference numerals or symbols refer to like elements throughout the disclosure and the drawings. For example, while each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like. As used herein, the term "and/or" includes any and all combinations of one or more of the associated listed elements.

It will be understood that, although the terms “first”, “second”, etc. may be used herein to describe various elements, the elements are not necessarily limited by these terms. These terms are used to distinguish one element from another element. For example, a first element could be termed a second element, or vice versa, without departing from the scope of the inventive concept. In the present disclosure, the singular expressions "a", "an" and "the" are intended to include the plural forms as well, unless the context clearly indicates otherwise.

In addition, the terms "below", “under”, "on the lower side", "above", “over”, "on the upper side", or the like may be used to describe the relationships between the elements illustrated in the drawings. These terms are relative concepts and are described on the basis of the directions indicated in the drawings.

It will be further understood that the terms "comprises, includes, has" and/or "comprising, including, having", when used in the present disclosure, specify the presence of stated features, numbers, steps, operations, elements, components or combinations thereof, but do not preclude the possibility of the presence or addition of one or more other features, numbers, steps, operations, elements, components, and/or combinations thereof. Hereinafter, embodiments of the inventive concept are described with reference to the drawings.

Embodiments of the present disclosure provide a display device including a first substrate, a second substrate, and a filling layer disposed between the first substrate and the second substrate. The first substrate includes a functional layer formed over a light control layer, the functional layer includes a barrier layer, a refraction compensation layer, and a hydrophobic thin film layer. The hydrophobic thin film layer faces the second substrate and directly contacts the filling layer.

By introducing a hydrophobic interface between the first substrate and the second substrate, embodiments of the present disclosure improve the uniformity of the filling layer during the bonding process. The hydrophobic surface repels hydrophilic filling material, and causing the filling material to spread evenly across the display region. This even distribution reduces the occurrence of voids or optical non-uniformities, thereby preventing stain defects that degrade display quality.

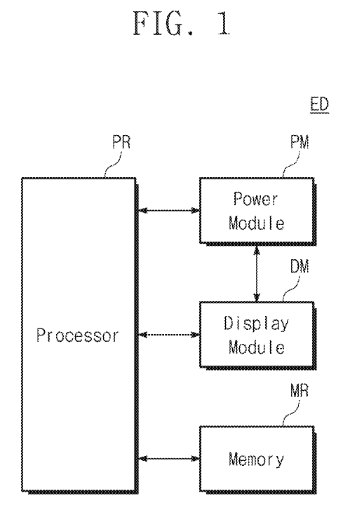

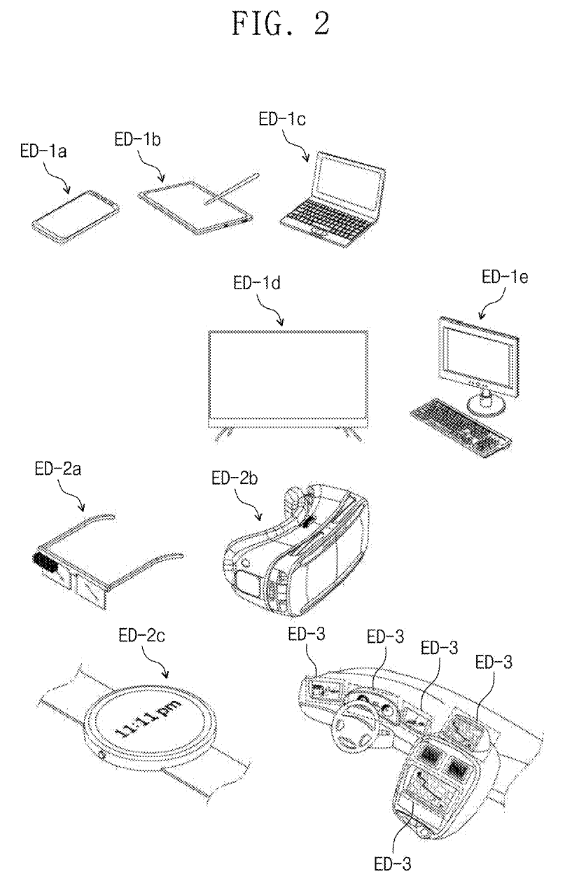

FIG. 1 is a block diagram of an electronic device according to an embodiment of the present disclosure. FIG. 2 illustrates schematic views of an electronic device according to various embodiments of the present disclosure.

FIG. 1 is a block diagram of an electronic device according to an embodiment of the present disclosure.

The electronic device ED according to the inventive concept may be provided in various forms. The electronic device ED further include a module or device having other additional functions. In some embodiments, the electronic device ED may be implemented in various devices described with reference to FIG. 2.

Referring to FIG. 1, an electronic device ED according to an embodiment may include a display module DM, a processor PR, a memory MR, and a power module PM.

The processor PR may include at least one among a central processing unit (CPU), an application processor (AP), a graphic processing unit (GPU), a communication processor (CP), an image signal processor (ISP), and a controller. In some cases, the processor PR may control the overall operation of the electronic device ED, including driving the display module DM based on image and data signals stored in memory MR. The power module PM may supply and control electrical power provided to each of the functional components.

The memory MR may include data information (or instructions) for operating the processor PR or the display module DM. When the processor PR executes an application stored in the memory MR, an image data signal and/or an input control signal may be transferred to the display module DM, and the display module DM may process the received signal and output image information through a display screen. In some cases, the display screen may correspond to a front-facing surface of the electronic device.

The power module PM may include a power supply module, such as a power adaptor or a battery device, and a power conversion module that converts power supplied by the power supply module to generate power for operating the electronic device ED.

A portion of functional modules may be included in the display module DM, and remaining functional modules may be provided in the electronic device ED separately from the display module DM.

FIG. 2 illustrates schematic views of an electronic device according to various embodiments of the present disclosure. For example, FIG. 2 shows a range of applicable form in which the inventive display device may be implemented. However, embodiments of the present disclosure are not necessarily limited thereto.

Referring to FIG. 2, the electronic device be implemented in an image-displaying electronic device, such as a smartphone ED-1a, a tablet computer ED-1b, a laptop computer ED-1c, a television (TV) ED-1d, or a desktop monitor ED-1e. In some cases, the electronic device be implemented in a wearable electronic device including a display module, such as smart glasses ED-2a, a head-mounted display ED-2b, or a smart watch ED-2c. In some cases, the electronic device be implemented in a vehicular electronic device ED-3 including a display module, such as a car dashboard, a center facia, a center information display (CID) disposed in a dashboard, or a room mirror display.

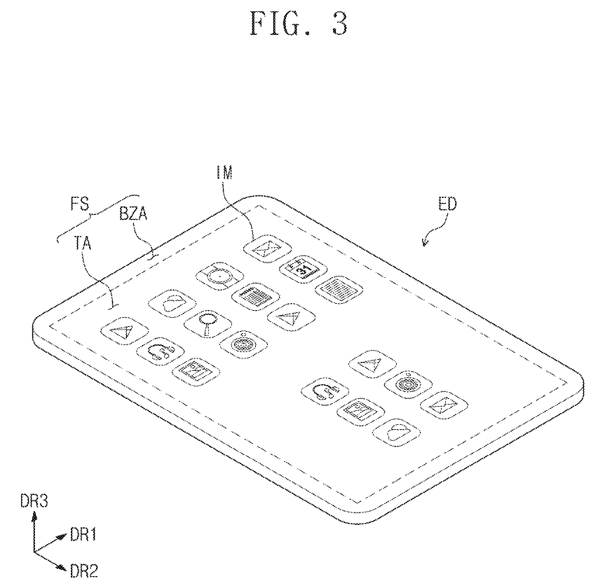

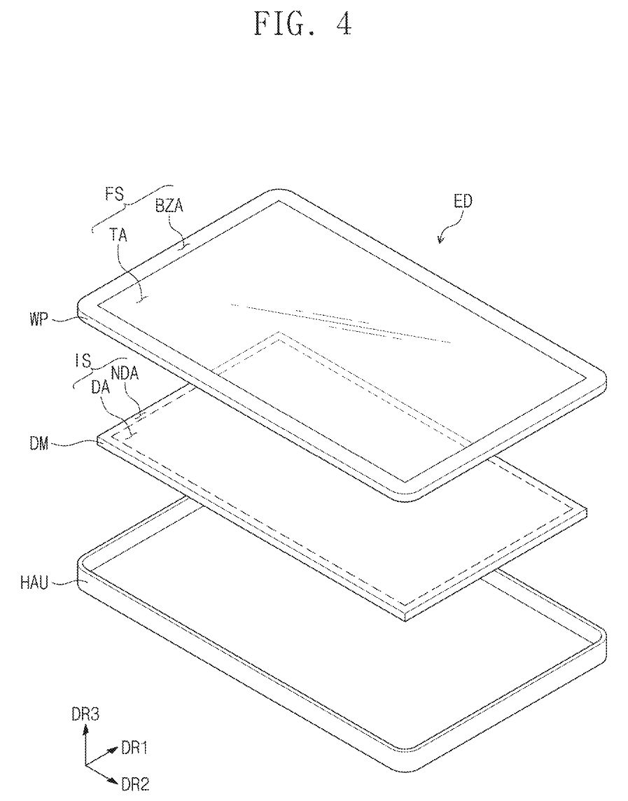

FIG. 3 is a perspective view of an electronic device according to an embodiment of the present disclosure. FIG. 4 is an exploded perspective view of an electronic device according to an embodiment of the present disclosure.

In an embodiment, the electronic device ED may have, in a plan view, a rectangular shape having short sides extending in a first direction DR1 and long sides extending in a second direction DR2. The second direction DR2 may cross (or is perpendicular to) the first direction DR1. However, an the shape of the electronic device ED is not necessarily limited thereto, and the electronic device ED may have various shapes, such as a circular shape and a polygonal shape.

The electronic device ED may display an image IM in a third direction DR3 through a display surface FS parallel to a plane defined by the first direction DR1 and the second direction DR2. The third direction DR3 may be substantially parallel to a normal direction of the display surface FS. The display surface FS, on which the image IM is displayed, may correspond to a front surface of the electronic device ED. The image IM may include a still image and/or a moving image (e.g., a video). In FIG. 3, icon images are illustrated as an example of the image IM.

In an embodiment, a front surface (or upper surface) and a rear surface (or lower surface) of each structural member or unit may be oriented based on a direction in which the image IM is displayed. The front surface and the rear surface may be opposed to each other in the third direction DR3, and a normal direction of each of the front surface and the rear surface may be parallel to the third direction DR3. A separation distance between the front surface and the rear surface extending along the third direction DR3 may correspond to a thickness of the structural member (or unit).

In the present disclosure, “on a plane” may be referred to as a state viewed from the third direction DR3. In the present disclosure, “on a cross-section” may be referred to as a state viewed from the first direction DR1 or the second direction DR2. Meanwhile, the directions indicated by the first, second, and third directions DR1, DR2, and DR3 are relative concepts and may vary based on the viewing angle or mounting orientation.

In the electronic device ED, the display surface FS on which the image IM is displayed may correspond to the front surface of the electronic device ED and may correspond to a front surface FS of a window WP (see FIG. 4). Hereinafter, the display surface and front surface of the electronic device ED and the front surface of the window WP are denoted as the same reference numeral or symbol. In some cases, for example, the electronic device ED may include a foldable display device that includes a folding region and a non-folding region, or a bendable display device that includes at least one bending part.

Referring to FIG. 4, the electronic device ED may include the window WP, the display module DM, and a case HAU. In some cases, the display module DM may be referred to as the display device.

The window WP may include an optically transparent insulating material. The window WP may include a transmission region TA and a bezel region BZA. A user may view an image provided through the transmission region TA corresponding to the front surface FS of the window WP. The transmission region TA may correspond to the display surface FS and allow visual output of image IM from the display module DM.

The transmission region TA may be an optically transparent region. The bezel region BZA may be a region having a relatively low light transmittance compared to the transmission region TA. In some cases, the bezel region BZA may have a predetermined color. The bezel region BZA may be adjacent to the transmission region TA and may surround the transmission region TA. The bezel region BZA may outline the shape of the transmission region TA. For example, the transmission region TA may have a shape that is visually bounded or outlined by the surrounding bezel region BZA. However, the embodiment is not necessarily limited thereto. For example, the bezel region BZA may be disposed adjacent to one side of the transmission region TA, or a portion of transmission region TA might not be surrounded by the bezel region BZA.

In FIGS. 3 and 4, the transmission region TA is illustrated as a quadrilateral shape. However, this is illustrated as an example, and the transmission region TA may have various shapes and is not necessarily limited thereto. Alternative geometries may include circular, elliptical, or irregular outlines based on design of the electronic device.

The display module DM may be disposed under the window WP. The display module DM may generate the image IM. The image IM generated by the display module DM is displayed on a display surface IS and is viewed by the user through the transmission region TA from the outside. In some cases, the image IM may be emitted through a display surface IS, which faces the transmission region TA, allowing the image IM to be externally visible through the window WP.

The display module DM includes a display region DA and a non-display region NDA. In some cases, the display module DM may include the display surface IS, where the display surface IS includes the display region DA and the non-display region NDA. The display region DA may be a region that is activated in response to an electrical signal. The non-display region NDA may be a region covered by the bezel region BZA. The non-display region NDA is adjacent to and surrounds the display region DA along one or more sides on a plane corresponding to the display surface IS.

The case HAU may house the display module DM. The case HAU may provide a base space in which the display module DM is to be disposed. The case HAU may cover the display module DM such that an upper surface of the electronic device ED can be exposed. The case HAU may cover a side surface and a bottom surface of the display module DM and may one or more regions of the upper surface of the display module DM. However, an embodiment is not necessarily limited thereto, and the case HAU may cover a portion of the upper surface, the side surface, and the bottom surface of the display module DM.

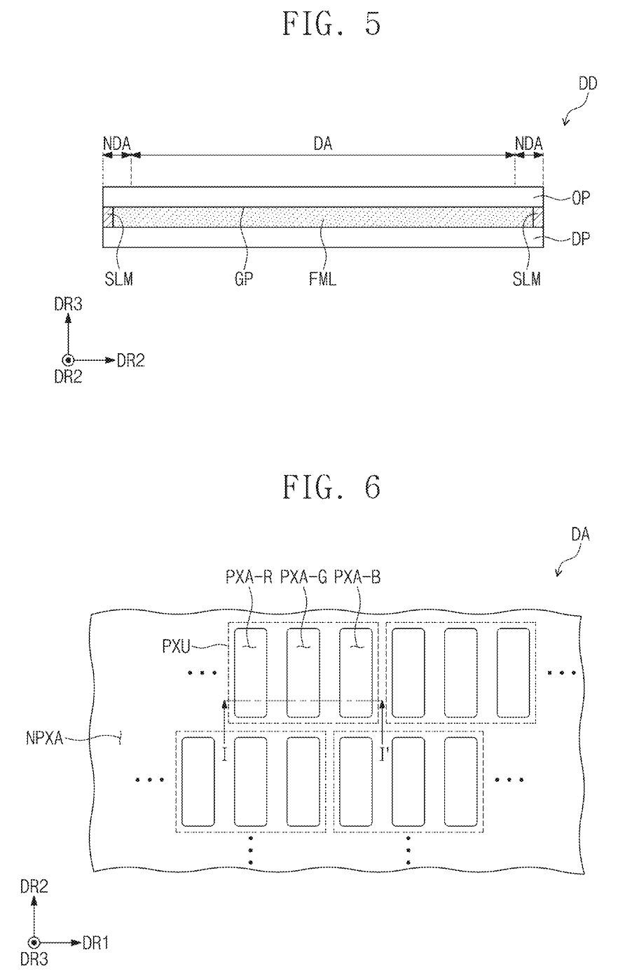

FIG. 5 is a cross-sectional view of a display device according to an embodiment of the present disclosure.

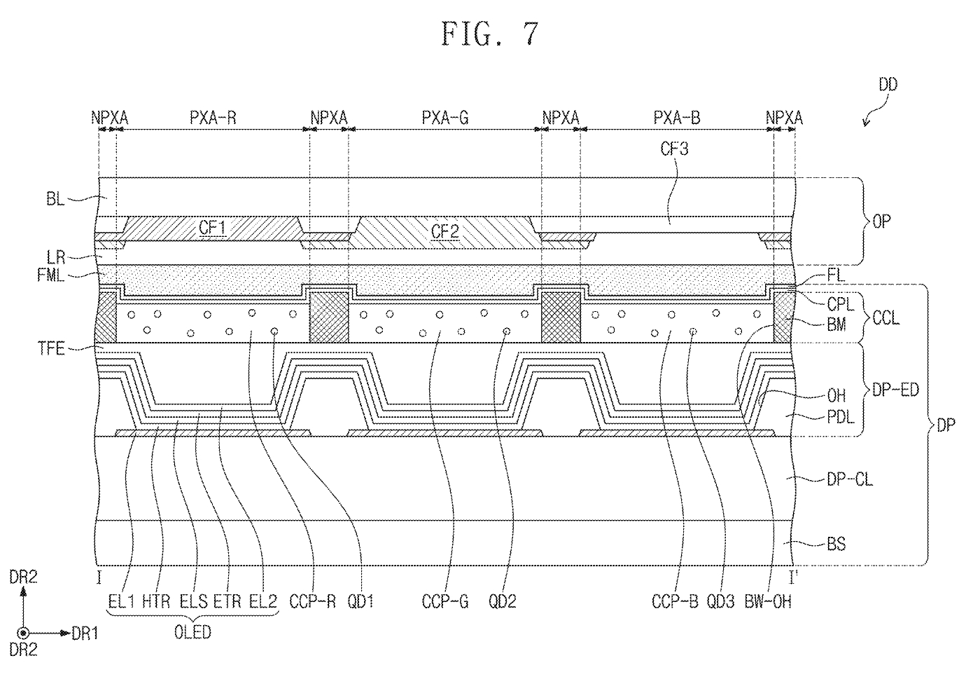

Referring to FIG. 5, a display device DD may include a first substrate DP, a second substrate OP that faces the first substrate DP and is spaced apart from the first substrate DP, and sealing members SLM that are disposed between the first substrate DP and the second substrate OP and overlap the non-display region NDA. Structural and functional components included in the first substrate DP and the second substrate OP are described with reference to FIG. 7.

The sealing members SLM may overlap the non-display region NDA, and the display region DA may be disposed in between the sealing members SLM in the second direction DR2. It is illustrated that the sealing members SLM are aligned with edges of the second substrate OP on a plane, but an embodiment of the inventive concept is not necessarily limited thereto. For example, the sealing members SLM may alternatively be disposed inward from the substrate edges within the non-display region NDA.

The sealing members SLM may include a binder resin and inorganic fillers mixed with the binder resin. The sealing members SLM may further include other additives. The additives may include an amine-based curing agent and a photoinitiator. The additives may further include a silane-based additive and an acrylic additive. The sealing members SLM may also include an inorganic material such as a frit.

A space enclosed by the first substrate DP, the second substrate, and the sealing members SLM may form a cell gap GP. The display device DD may further include a filling layer FML disposed in the cell gap GP. The filling layer FML may overlap the display region DA and at least a portion of the non-display region NDA, thereby extending across both active and inactive areas of the display device.

In one aspect, the spreadability of the filling layer FML may be enhanced such that the filling layer FML compactly fills the cell gap GP during bonding of the first substrate DP and the second substrate OP. The enhanced spreadability may reduce a phenomenon in which the filling layer FML is unevenly formed, which may result an observable stain on the display device DD.

FIG. 6 is an enlarged plan view of a portion of a display region in a display device according to an embodiment of the present disclosure. For example, FIG. 6 illustrates the pixel layout within the display region DA and the arrangement of one or more pixel units and the subpixel components.

Referring to FIG. 6, pixel units PXU may be respectively arranged in a first direction DR1 and a second direction DR2. In an embodiment, each of the pixel units PXU may include a first pixel, a second pixel, and a third pixel, which emit light having different wavelength ranges. The first pixel, the second pixel, and the third pixel may emit red light, green light, and blue light, respectively. In FIG. 6, a first pixel region PXA-R, a second pixel region PXA-G, and a third pixel region PXA-B are illustrated to represent the first pixel, the second pixel, and the third pixel, respectively.

The first pixel region PXA-R may be a region through which the light generated from the first pixel is emitted externally. The second pixel region PXA-G may be a region through which the light generated from the second pixel is emitted externally. The third pixel region PXA-B may be a region through which the light generated from the third pixel is emitted externally. The first, second, and third pixel regions PXA-R, PXA-G, and PXA-B may be separated from each other and not overlap each other on a plane.

In an embodiment, the first pixel region PXA-R may be a region that emits red light, the second pixel region PXA-G may be a region that emits green light, and the third pixel region PXA-B may be a region that emits blue light. However, an embodiment of the inventive concept is not necessarily limited thereto. For example, the display region DA may further include a pixel region that emits white light in addition to the first, second, and third pixel regions PXA-R, PXA-G, and PXA-B.

A peripheral region NPXA may be arranged to surround each of the first pixel region PXA-R, the second pixel region PXA-G, and the third pixel region PXA-B. Additionally, the peripheral region NPXA may be disposed between the first pixel region PXA-R, the second pixel region PXA-G, and the third pixel region PXA-B. The peripheral region NPXA may serve as a physical and optical separator for the first, second, and third regions PXA-R, PXA-G, and PXA-B. The peripheral region NPXA may prevent color mixing between the first, second, and third pixel regions PXA-R, PXA-G, and PXA-B.

A structure configured to reduce or prevent color mixing between the first, second, and third pixel regions PXA-R, PXA-G, and PXA-B (such as a pixel definition layer PDL or a division pattern BM described with reference to FIG. 7) may be disposed in the peripheral region NPXA. In some cases, these elements may serve as light-blocking or isolation structures to enhance color fidelity and minimize optical crosstalk between adjacent subpixels.

In FIG. 6, the first, second, and third pixel regions PXA-R, PXA-G, and PXA-B, which have the same planar shape and area, are illustrated as an example, but an embodiment of the inventive concept is not necessarily limited thereto. The areas of the first, second, and third pixel regions PXA-R, PXA-G, and PXA-B may be substantially the same, or the area of at least one of the pixel regions may be different from the areas of the other pixel regions. The areas of the first, second, and third pixel regions PXA-R, PXA-G, and PXA-B may be determined based on the color of light emitted.

In an embodiment, the first, second, and third pixel regions PXA-R, PXA-G, and PXA-B may have, in the plan view, a rectangular shape (substantially rectangular shape) with rounded corners. However, an embodiment of the inventive concept is not necessarily limited thereto, and the first, second, and third pixel regions PXA-R, PXA-G, and PXA-B may have other shapes such as a polygonal shape (including a substantial polygonal shape) such as a rhombus or pentagon. The shape of the pixel regions PXA-R, PXA-G, and PXA-B may vary based on the pixel density, aperture ratio, or subpixel layout plan.

The pixel regions PXA-R, PXA-G, and PXA-B may be aligned and arranged in a stripe form, or may follow an arrangement such as PENTILE™ or Diamond Pixel™. However, an embodiment is not necessarily limited thereto, and the arrangement order or form of the pixel regions PXA-R, PXA-G, and PXA-B may be provided in various combinations based on characteristics of the display quality for the display device DD (see FIG. 4). In some cases, the arrangement may be based on factors such as resolution, subpixel rendering, power efficiency, or visual performance.

FIG. 7 is a cross-sectional view illustrating a portion of a display device according to an embodiment of the present disclosure. FIG. 7 may be a cross-sectional view taken along line I-I' of FIG. 6.

Referring to FIG. 7, the display device DD may include a first substrate DP, a second substrate OP, and a filling layer FML disposed between the first substrate DP and the second substrate OP. The illustrated cross-sectional region I-I’ corresponding to the pixel regions PXA-R, PXA-G, and PXA-B and the adjacent peripheral region NPXA shown in FIG. 6.

Referring to FIG. 7, the first substrate DP may include a base layer BS, a circuit element layer DP-CL disposed on the base layer BS, a display element layer DP-ED disposed on the circuit element layer DP-CL, and a light control layer CCL disposed on the display element layer. In one aspect, the display element layer DP-ED may include a pixel definition layer PDL, a pixel opening OH, and an encapsulation layer TFE. The light control layer CCL may include a division pattern BM and a capping layer CPL.

The base layer BS may provide a base surface on which the circuit element layer DP-CL and the display element layer DP-ED are disposed. The base layer BS may be a glass substrate, a metal substrate, a polymer substrate, or other substrate materials. However, an embodiment of the inventive concept is not necessarily limited thereto, and the base layer BS may be formed of an inorganic layer, a functional layer, or a composite material layer. In some cases, the base layer BS may include one or more sub-layers to form a multi-layer structure, which may provide increased mechanical strength, thermal stability, or light transmittance properties.

The circuit element layer DP-CL may be disposed on the base layer BS. The circuit element layer DP-CL may include an insulating layer, a semiconductor pattern, a conductive pattern, a signal line, and other components. The insulating layer, the semiconductor layer, and the conductive layer are formed on the base layer BS through coating, deposition, and then, the insulating layer, the semiconductor layer, and the conductive layer may be selectively patterned by performing a photolithography process. Thereafter, the semiconductor pattern, the conductive pattern, and the signal line included in the circuit element layer DP-CL may be formed. In an embodiment, the circuit element layer DP-CL may include a transistor, a buffer layer, and insulating layers.

The display element layer DP-ED may be disposed on the circuit element layer DP-CL. The display element layer DP-ED may include a pixel definition layer PDL, a light-emitting element ED, and an encapsulation layer TFE. The pixel definition layer PDL may outline the subpixel boundaries and emission areas for enhanced color separation. The light-emitting element ED may include an organic light-emitting diode OLED. The encapsulation layer TFE may seal and planarize the display element layer DP-ED to prevent ingress of moisture and oxygen.

A light-emitting element OLED may generate source light. In an embodiment, the source light may include light of a blue light wavelength range. However, an embodiment of the inventive concept is not necessarily limited thereto. For example, the source light may include white light, or light-emitting elements OLED corresponding to respective pixel regions provide different source light. In some embodiments, one or more light-emitting elements OLED may emit red light, green light, and blue light independently, or a common white-emitting OLED may be used in combination with color filters to form the color pixels.

The light-emitting element OLED may include a first electrode EL1, a second electrode EL2 facing the first electrode EL1, and a light-emitting part ELS disposed between the first electrode EL1 and the second electrode EL2. In an embodiment, the light-emitting part ELS may include an organic light-emitting material. The light-emitting element OLED may further include a hole transfer region HTR and an electron transfer region ETR. In some cases, the light-emitting element OLED may further include a capping layer disposed on the second electrode EL2.

The pixel definition layer PDL may be disposed on the circuit element layer DP-CL. The pixel definition layer PDL may cover a portion of the first electrode EL1. A pixel opening OH may be formed in the pixel definition layer PDL. The pixel opening OH may expose at least a portion of the first electrode EL1. A region in which the first electrode EL1 is exposed by the pixel opening OH may correspond to a light-emitting region, in which light can be generated and emitted.

The pixel definition layer PDL may include a polymer resin. For example, the pixel definition layer PDL may include a polyacrylate-based resin or a polyimide-based resin. Additionally, the pixel definition layer PDL may be formed by a light absorbing material, or may include a black pigment or black dye, or include, for example, carbon black. In addition, the pixel definition layer PDL may be formed of an inorganic material. For example, the pixel definition layer PDL may be formed of an inorganic material such as silicon nitride (SiNx), silicon oxide (SiOx), and silicon oxynitride (SiOxNy).

The first electrode EL1 may be disposed on the circuit element layer DP-CL. The first electrode EL1 may serve as an anode or a cathode. Additionally, the first electrode EL1 may function as a pixel electrode for driving each light-emitting region. The first electrode EL1 may be a transmissive electrode, a transflective electrode, or a reflective electrode.

The second electrode EL2 may be disposed on the first electrode EL1. The second electrode EL2 may be a cathode or an anode. In an embodiment, when the first electrode EL1 is an anode, the second electrode EL2 may be a cathode, or vice versa. The second electrode EL2 may be a common electrode. However, an embodiment is not necessarily limited thereto. The second electrode EL2 may be a transmissive electrode, a transflective electrode, or a reflective electrode.

In an embodiment, the light-emitting part ELS may be provided as a single light-emitting layer or an emission stack in which a plurality of emission units are stacked. When the light-emitting part ELS is an emission stack , the light-emitting part ELS may include two or more emission stacks that are distinct from each other and stacked in a third direction DR3 corresponding to the thickness direction. Each of the emission units may include at least one light-emitting layers.

The encapsulation layer TFE may be disposed on the second electrode EL2. The encapsulation layer TFE may cover the light-emitting element OLED. The encapsulation layer TFE may be a thin film encapsulation layer. The encapsulation layer TFE may have a single layer or a multi-layer in which a plurality of layers are stacked. The encapsulation layer TFE may include at least one insulating layer. The encapsulation layer TFE may include at least one inorganic layer (hereinafter, inorganic encapsulation film). In some embodiments, the encapsulation layer TFE may include an inorganic encapsulation film and an organic encapsulation film, which may be alternately stacked to form a multilayer barrier. For example, the inorganic encapsulation film may include at least one organic layer (hereinafter, organic encapsulation film) and at least one inorganic encapsulation film. The inorganic encapsulation film may protect the light-emitting element OLED from moisture and oxygen, and the organic encapsulation film may protect the light-emitting element OLED from foreign substances such as dust particles. In some cases, the organic film may also serve as a stress-relief buffer layer to mitigate cracking in the inorganic layers.

The second substrate OP may be disposed on the first substrate DP. For example, the second substrate OP may be referred to as a “light control panel”. The light control panel OP may include a base substrate BL, a low refraction layer LL, and a color filter layer CFL. However, an embodiment of the inventive concept is not necessarily limited thereto. For example, the light control panel OP might not include the low refraction layer LL and the color filter layer CFL.

In the light control panel OP according to an embodiment of FIG. 5, the base substrate BL may provide a base surface on which the color filter layer CFL, the low refraction layer LL, and the light control layer CCL are disposed. The base substrate BL may be a glass substrate, a metal substrate, a plastic substrate, and other substrate materials. However, an embodiment is not necessarily limited thereto. The base substrate BL may be an inorganic layer, an organic layer, or a composite material layer.

In an embodiment, the light control layer CCL may further include the division pattern BM, light control parts CCP-R, CCP-G, and CCP-B, and a capping layer CPL. The light control parts CCP-R, CCP-G, and CCP-B may correspond to red, green, and blue subpixels, respectively, and may be configured to control the wavelength or intensity of emitted light passing through each corresponding region.

The division pattern BM may separate a plurality of light control parts CCP-R, CCP-G, and CCP-B from each other. The division pattern BM may include a base resin and an additive. The additive may include a coupling agent and/or a photoinitiator. The additive may further include a dispersant. The division pattern BM may include a black coloring agent for light-blocking. The division pattern BM may include black dye or a black pigment mixed into the base resin. In an embodiment, the black coloring agent may include carbon black, a metal such as chromium, or an oxide thereof.

In an embodiment, a barrier layer BR and a refraction compensation layer LR may include at least one of polyimide, polycarbonate, polyethylene, polyvinyl carbonate, silicon nitride (SiNx), and silicon oxide (SiOx). For example, the barrier layer BR may include silicon nitride (SiNx), and the refraction compensation layer LR may include silicon oxide (SiOx).

An opening BW-OH that overlaps the pixel opening OH may be formed in the division pattern BM. In an embodiment, the light control layer CCL may include a first light control part CCP-R corresponding to the first pixel region PXA-R, a second light control part CCP-G corresponding to the second pixel region PXA-G, and a third light control part CCP-B corresponding to the third pixel region PXA-B. In some cases, each light control part may be positioned to control the spectral or angular characteristics of light emitted from the corresponding pixel region.

At least one of the first, second, and third light control parts CCP-R, CCP-G, and CCP-B may include quantum dots that convert the optical property of the source light. The first light control part CCP-R may include first quantum dots QD1, the second light control part CCP-G may include second quantum dots QD2, and the third light control part CCP-B may include third quantum dots QD3.

The first light control part CCP-R may be a red-light control part that emits red light, the second light control part CCP-G may be a green-light control part that emits green light. The third light control part CCP-B may be a blue-light control part that emits blue light. Alternately, the third light control part CCP-B may be a transmission light control part that transmits and emits the source light.

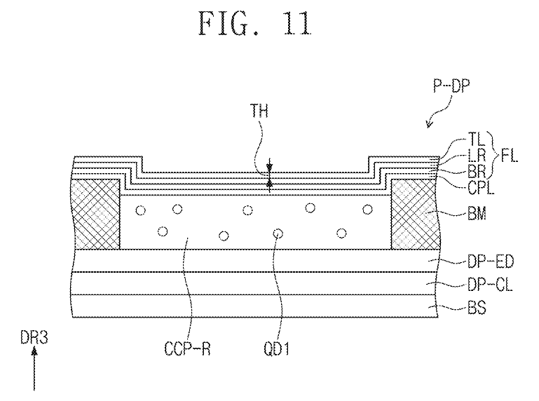

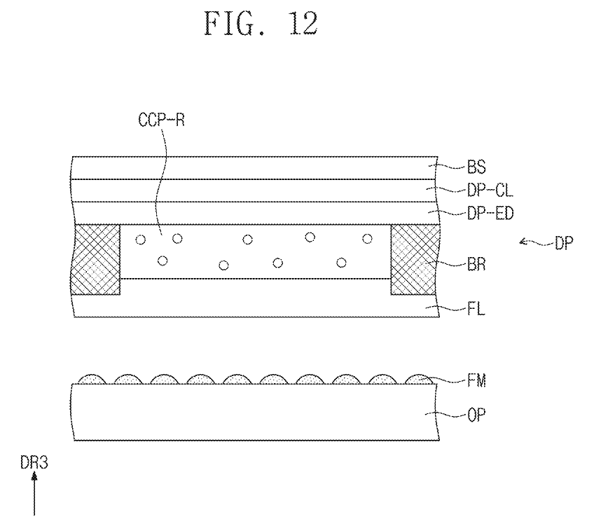

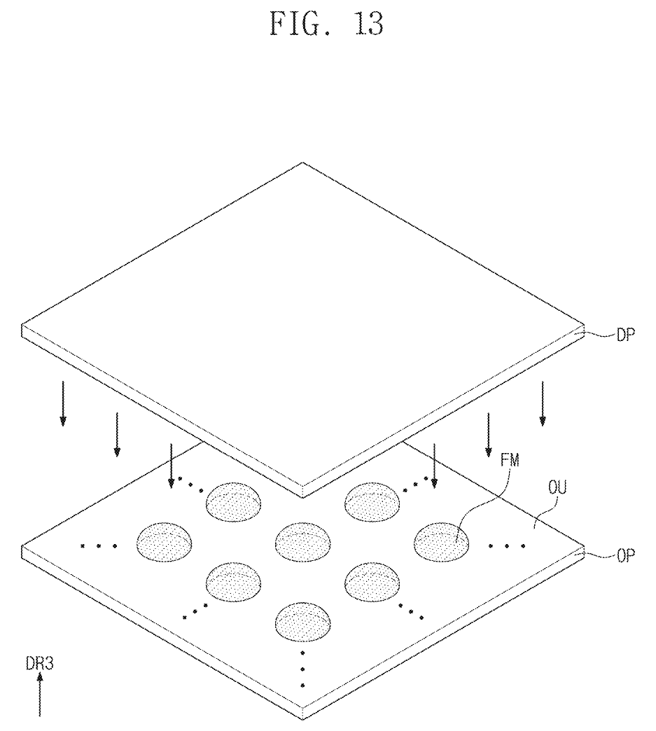

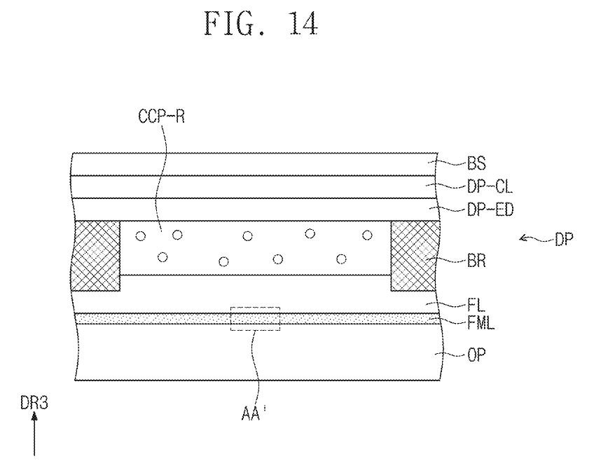

In an embodiment, a functional layer FL may be disposed on the capping layer CPL. The functional layer FL may include a hydrophobic material. Accordingly, a surface of which the functional layer FL faces the filling layer FML may exhibit hydrophobic characteristics. The functional layer FL may reduce the likelihood of filling materials FM (see FIG. 13), which are used for forming the filling layer FML, being unevenly spread between the first substrate DP and the second substrate OP due to a repulsive force of the hydrophobic surface. Further details regarding the interaction between the functional layer FL and the filling material FM are described with reference to FIGS. 11-19.

The functional layer FL may include the barrier layer BR, the refraction compensation layer LR disposed on the barrier layer BR, and a thin film layer TL disposed on the refraction compensation layer LR (See FIG. 11).

The barrier layer BR may be disposed on the capping layer CPL. The barrier layer BR may be a protective layer that prevents the refraction compensation layer LR and the thin film layer TL from being physically or chemically damaged. The barrier layer may serve as a structural shield, particularly against moisture, oxygen, and mechanical abrasion during panel stacking or encapsulation.

The refraction compensation layer LR may be disposed on the barrier layer BR. The refraction compensation layer LR may enhance optical output by compensating for reduced light efficiency of the display device DD. The refraction compensation layer LR may be directly disposed on the barrier layer BR. The refraction compensation layer LR may have a refractive index of about 1.68 to about 1.8.

The thin film layer TL may be disposed on the refraction compensation layer LR. The thin film layer TL may be directly formed on and disposed on the refraction compensation layer LR without an intervening layer. The thin film layer TL may be formed through atomic layer deposition. The thin film layer TL may include aluminum oxide (AL₂O₃). The thin film layer TL may have a thickness TH (see FIG. 11) of about 0.01 μm to about 2 μm.

The filling layer FML may be disposed between the first substrate DP and the second substrate OP. The filling layer FML may be directly disposed on the thin film layer TL. A filling material FM (see FIG. 13) for forming the filling layer FML may include water and a solvent containing alcohol or other hydrophilic solvents. The filling material FM (see FIG. 13) may further include an organic material. For example, the filling material FM (see FIG. 13) may further include an epoxy-based organic material. In some cases, the composition of the filling material FM may be selected to enhance uniform spreading with the surface properties of the thin film layer TL.

In an embodiment, the display device DD may be formed such that the first substrate DP supports a vertically stacked structure having multiple functional layers. The base layer BS may form the lowermost portion of the first substrate DP, and the circuit element layer DP-CL is disposed on the base layer BS. The display element layer DP-ED may be disposed on the circuit element layer DP-CL and may include a pixel definition layer PDL, a light-emitting element OLED, and an encapsulation layer TFE. The light-emitting element OLED may include a first electrode EL1, a second electrode EL2, and a light-emitting part ELS disposed between the first electrode EL1 and the second electrode EL2. The encapsulation layer TFE, light control layer CCL may be formed on the light-emitting element OLED.

In one aspect, the light control layer CCL includes a division pattern BM, light control parts CCP-R, CCP-G, and CCP-B, and a capping layer CPL. A functional layer FL may be disposed on the capping layer CPL, where the functional layer FL includes a barrier layer BR, a refraction compensation layer LR, and a thin film layer TL. A filling layer FML may be disposed on the thin film layer TL of the functional layer FL, and may fill the cell gap between the first substrate DP and the second substrate OP. The second substrate OP, which may be referred to as a light control panel, may include a base substrate BL and may face the first substrate DP. This layered structure enables precise control of light emission, wavelength conversion, and mechanical protection within a compact device profile.

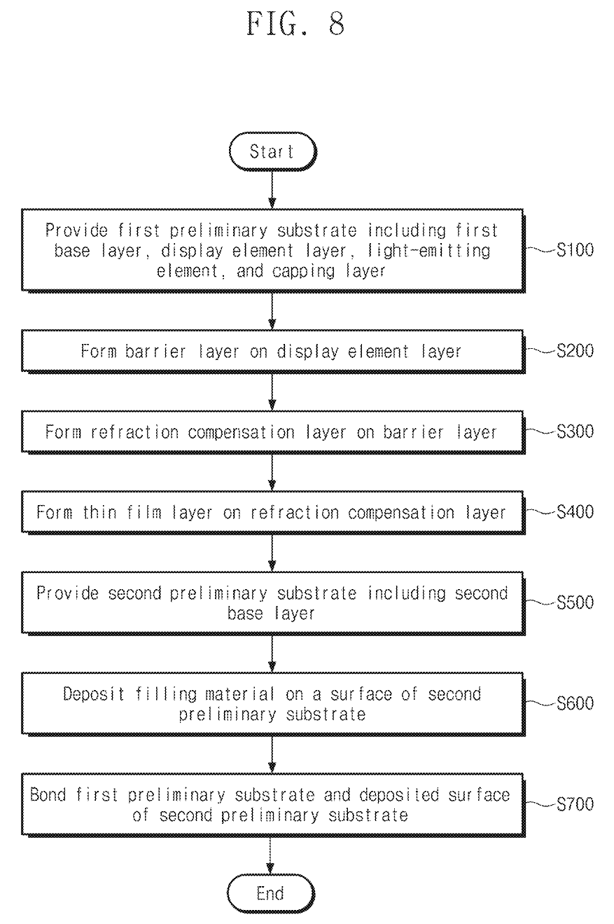

FIG. 8 is a block diagram of a method of manufacturing a display device according to an embodiment of the present disclosure.

The method for manufacturing the display device may include a sequence of operations. For example, at operation (or step) S100, the method includes providing a first preliminary substrate including a first base layer, a display element layer including a light-emitting element disposed on the first base layer, a light control layer including a division pattern disposed on the display element layer and having an opening in the light control layer CCL, a light control part disposed in the opening, and a capping layer disposed on the light control part. At operation S200, the method includes forming a barrier layer on the display element layer. At operation S300, the method includes forming a refraction compensation layer on the barrier layer. At operation S400, the method includes forming a thin film layer including a hydrophobic material on the refraction compensation layer. At operation S500, the method includes providing a second preliminary substrate including a second base layer. At operation S600, the method includes depositing filling materials on a surface of the second preliminary substrate. At operation S700, the method includes bonding the first preliminary substrate and the deposited surface of the second preliminary substrate (S700).

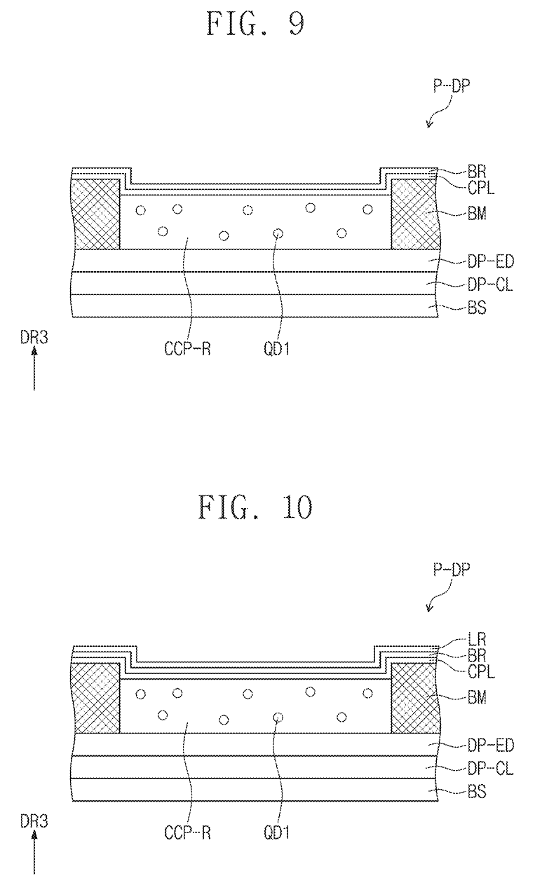

Hereinafter, although the first light control part CCP-R is illustrated as an example of the light control parts CCP-R, CCP-G, and CCP-B in FIGS. 9 to 12, such illustration is provided for the convenience of explanation. The description made with reference to the first light control part CCP-R may be equally applicable to the second light control part CCP-G (see FIG. 7) and the third light control part CCP-B (see FIG. 7).

In FIG. 9, after providing the first preliminary substrate P-DP (S100) (see FIG. 8), the barrier layer may be formed on the first preliminary substrate P-DP (S200) (see FIG. 8). For example, the first preliminary substrate P-DP may be referred to as the uncompleted first substrate DP (see FIG. 5) which is undergoing a manufacturing process. In an embodiment, the barrier layer BR may include silicon nitride (SiNx).

The first preliminary substrate P-DP includes a stack of layers formed in a sequential order. For example, the first preliminary substrate P-DP includes a first base layer BS, a circuit element layer DP-CL disposed on the first base, a display element layer DP-ED disposed on the circuit element layer DP-CL, where the display element layer DP-ED includes a light-emitting element, a light control layer CCL including a division pattern BM formed on the display element layer, where the light control layer CCL includes an opening, a light control part (e.g., first light control part CCP-R, second light control part CCP-G, or third light control part CCP-B) disposed in the opening, and a capping layer CPL disposed on the light control part CCP-R. In an embodiment, the barrier layer BR is disposed on the capping layer CPL.

Referring to FIG. 10, at operation S330, a refraction compensation layer LR is formed on the barrier layer BR. In an embodiment, the refraction compensation layer LR may include silicon oxide (SiOx). In an embodiment, the refraction compensation layer LR may be uniformed disposed on the barrier layer BR.

Referring to FIG. 11, at operation S400, a thin film layer TL including a hydrophobic material is disposed on the refraction compensation layer LR.

In an embodiment, the thin film layer TL may be formed by depositing aluminum oxide (Al₂O₃) on the refraction compensation layer LR using atomic layer deposition (ALD). The thin film layer may be formed to a thickness of about 0.01 μm to about 2 μm. Accordingly, the functional layer FL may include the barrier layer BR, the refraction compensation layer LR disposed on the barrier layer BR, and the thin film layer TL disposed on the refraction compensation layer LR.

Referring to FIGS. 12 and 13, at operations S500 and S600, the second substrate OP including the second base layer may be provided, and the filling materials FM may be deposited onto the second substrate.

The first substrate DP illustrated in FIG. 12 may be shown in an inverted orientation compared to the first preliminary substrate P-DP illustrated in FIGS. 9 to 11. For example, the first substrate DP may be inverted such that the upper surface of the first preliminary substrate P-DP may face downward towards an upper surface of the second substrate OP.

The provided second substrate OP may be disposed under the first substrate DP. For example, the upper surface of the second substrate OP may face the upper surface of the first substrate DP (or the lower surface of the inverted first substrate DP).

The filling materials FM may be ejected onto an upper surface of the second substrate OP using an inkjetting method. The filling materials FM may be spaced apart from each other at a predetermined interval. FIG. 13 illustrates that the ejected filling materials FM have a hemispherical shape. However, an embodiment of the inventive concept is not necessarily limited thereto.

Referring to FIG. 14, at operation S700, the first substrate DP and the second substrate OP may be bonded together. For example, the first substrate DP may be brought in contact with the second substrate OP. However, the bonding process is not necessarily limited to a specific direction as long as the relative distance between the first substrate DP and the second substrate OP become smaller is reduced to contact.

The filling materials FM, once disposed between the first substrate DP and the second substrate OP, may spread along the interface between the first substrate DP and the second substrate OP. The filling materials FM that have been spread may fill the cell gap GP (described with reference to FIG. 5) between the first substrate DP and the second substrate OP.

For example, due to the hydrophobic surface of the thin film layer TL and the repulsive interaction with the hydrophilic filling material FM, the filling material may spread evenly and uniformly throughout the cell gap GP. This uniform distribution prevents voids or uneven regions that can lead to stain defects, thereby enhancing the display quality and reliability of the display device DD.

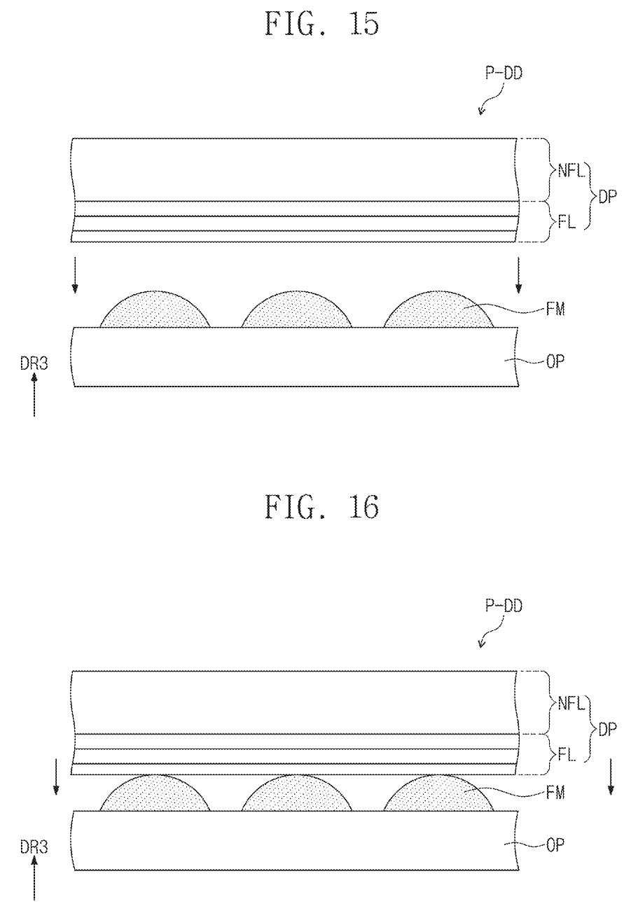

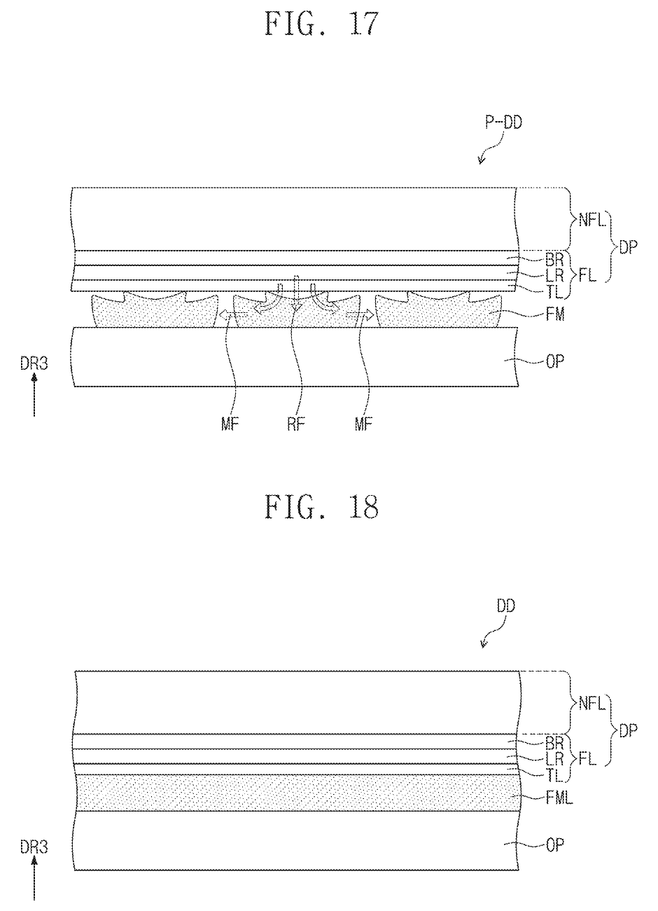

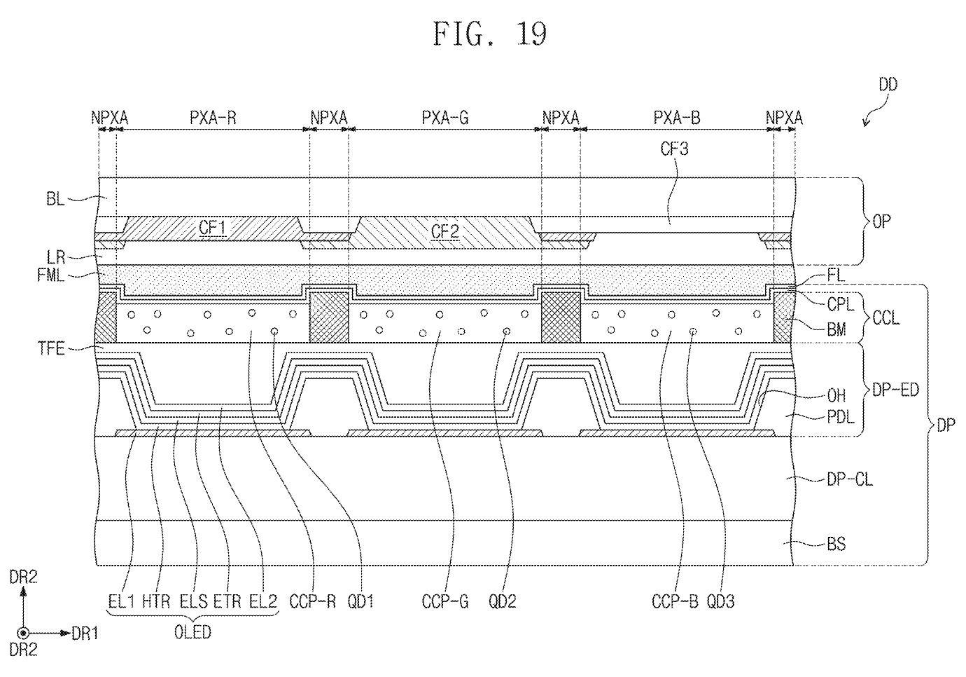

FIGS. 15 to 18 are cross-sectional views of respective steps for the method of manufacturing the display device for explaining the spreading phenomenon of the filling material FM between the first substrate DP and the second substrate OP.

In FIG. 15, the first substrate DP including the functional layer FL is positioned above the second substrate OP, on which hemispherical droplets of the filling material FM have been deposited. FIG. 16 illustrates that the two substrates bringing the hydrophobic surface of the thin film layer TL into proximity with the filling material FM. In FIG. 17, as the two substrates move closer, the filling material FM spreads through along the upper surface of the second substrate OP. In FIG. 18, the filling material FM is evenly spread and forms the filling layer FML between the first substrate DP and the second substrate OP.

In one aspect, components of the first substrate DP other than the functional layer FL may be referred to as a lower layer NFL in the drawing.

Referring to FIGS. 16 to 18, the thin film layer TL may be in contact with the filling material FM.

Accordingly, since the thin film layer TL has a hydrophobic property and the filling material FM includes water or alcohol, the thin film layer TL and the filling material may be repulsive to each other. As the filling material FM comes into contact with the thin film layer TL, a repulsive force RF may be applied. For convenience of explanation, FIG. 17 illustrates the repulsive force RF received by the filling material FM as an arrow.

Due to the repulsive force, the spreadability of the filling material FM may be enhanced. FIG. 18 illustrates as an example that a movement MF of the filling material FM becomes larger. Accordingly, the filling material FM may compactly fill a space between the first substrate DP and the second substrate OP without a gap. This hydrophobic-hydrophilic repulsion ensures that the filling material FM spreads evenly across the bonding interface between the first substrate DP and the second substrate OP, forming a continuous and uniform filling layer FML. Accordingly, voids and uneven regions are minimized, and stain defects can be prevented.

FIG. 19 is a cross-sectional view illustrating the display device DD completed using the method described by the method according to embodiments of the present disclosure. Referring to FIG. 19, the filling material FM may fill a space between the first substrate DP and the second substrate OP without a gap, forming the filling layer FML.

In an embodiment, the display device DD includes a first substrate DP having a base layer BS, a circuit element layer DP-CL, a display element layer DP-ED including OLEDs, and a light control layer CCL. A functional layer FL is disposed on the light control layer CCL and includes a barrier layer BR, a refraction compensation layer LR, and a thin film layer TL.

The second substrate OP, which faces the first substrate, includes first, second, and third color filters CF1, CF2, and CF3. The filling layer FML uniformly formed between the first substrate DP and second substate OP enhances optical clarity and prevents stain defects.

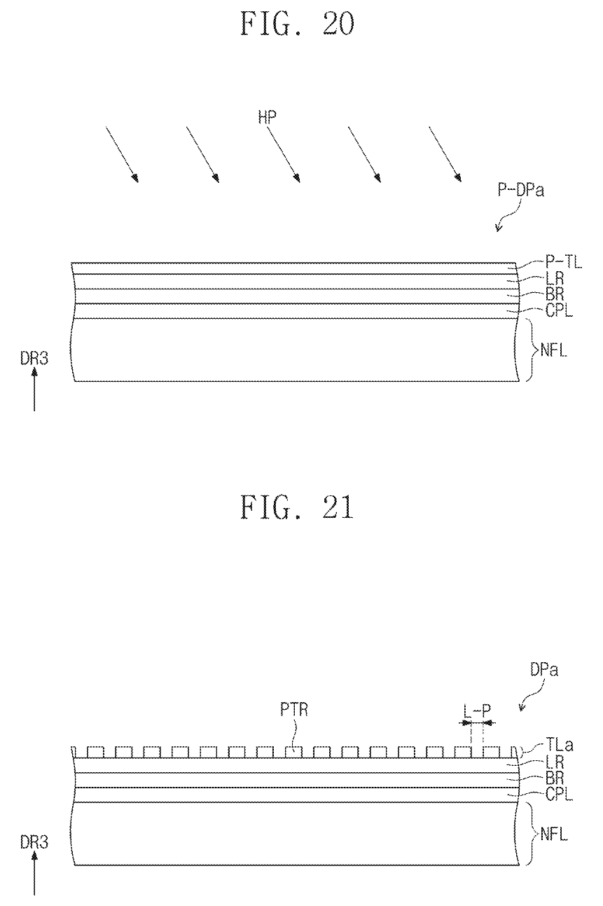

FIGS. 20 and 21 are diagrams illustrating respective steps of a method for manufacturing a display device according to an embodiment of the present disclosure.

The display device DD may include a first preliminary substrate P-DPa. The first preliminary substrate P-DPa may be formed by performing the same or similar steps for the method of manufacturing the display device described with reference to FIGS. 9 to 11. The same or similar components described with reference to FIGS. 1 to 11 are given the same or similar numerals or symbols, and the differences are described.

Referring to FIGS. 20 and 21, forming the thin film layer may include forming, on the refraction compensation layer LR, a preliminary thin film layer P-TL including silicon oxide or silicon nitride using chemical vapor deposition, and forming protrusions on the preliminary thin film layer P-TL by performing a plasma treatment process on the preliminary thin film layer P-TL.

In an embodiment, forming the preliminary thin film layer P-TL may be performed using chemical vapor deposition (CVD) of silicon oxide or silicon nitride.

In an embodiment, a plasma treatment process may be performed on the preliminary thin film layer P-TL. In an embodiment, the plasma treatment process may be a plasma treatment process using hydrogen or nitric acid. Accordingly, the protrusions PTR are formed on the preliminary thin film layer P-TL. The protrusions PTR are spaced apart from each other at a predetermined interval L-P. The protrusions PTR may have a shape protruding in the third direction DR3.

Accordingly, a thin film layer TLa may include protrusions PTR. The thin film layer TLa may have a hydrophobic property. In an embodiment, the thin film layer TLa may have a hydrophobic dendrite structure.

According to the inventive concept, the occurrence of a stain defect on a display device is prevented, and thus the display device with improved visibility may be provided. By promoting even spreading of filling materials due to enhanced surface hydrophobicity, stain defects may be prevented, thereby enhancing optical uniformity and visibility of the display device DD.

According to the inventive concept, a display device manufacturing method, which prevents the occurrence of a stain defect in the process of manufacturing a display device, may be provided.

In the above, description has been made with reference to embodiments of the inventive concept, but those skilled or of ordinary skill in the art may understand that various modifications and changes may be made to the inventive concept without departing from the spirit and technical scope of the inventive concept.

What is claimed is:

1. A display device comprising:
a first substrate comprising:
a first base layer,
a display element layer including a light-emitting element disposed on the first base layer,
a light control layer including a division pattern disposed on the display element layer and having an opening in the light control layer,
a light control part disposed in the opening, and
a functional layer disposed on the light control part;
a second substrate disposed on the first substrate and including a second base layer; and
a filling layer disposed between the first substrate and the second substrate,
wherein the functional layer includes a barrier layer, a refraction compensation layer disposed on the barrier layer, and a thin film layer disposed on the refraction compensation layer, and
wherein the thin film layer has a hydrophobic surface facing the second substrate.

2. The display device of claim 1, wherein:
the barrier layer includes silicon nitride,
the refraction compensation layer includes silicon oxide, and
the thin film layer includes aluminum oxide.

3. The display device of claim 1, wherein:
the barrier layer and the refraction compensation layer include at least one of polyimide, polycarbonate, polyethylene, or polyvinyl carbonate.

4. The display device of claim 1, wherein:
the thin film layer is directly disposed on the refraction compensation layer, and
the refraction compensation layer is directly disposed on the barrier layer.

5. The display device of claim 1, wherein:
the refraction compensation layer has a refractive index of about 1.68 to about 1.8, inclusive.

6. The display device of claim 1, wherein:
the thin film layer is formed using atomic layer deposition.

7. The display device of claim 1, wherein:
the thin film layer has a thickness of about 0.01 μm to about 2 μm, inclusive.

8. The display device of claim 1, wherein:
the light control part includes a first light control part, a second light control part, and a third light control part, and at least one of the first light control part, the second light control part, and the third light control part includes a quantum dot.

9. The display device of claim 1, wherein:
the filling layer comprises water or alcohol, and
the filling layer is directly disposed on the thin film layer.

10. The display device of claim 1, wherein:
the thin film layer comprises silicon oxide or silicon nitride, and
the thin film layer includes protrusions protruding toward the second substrate.

11. The display device of claim 1, wherein the second substrate further comprises:
a color filter layer disposed under the second base layer.

12. A method for manufacturing a display device, the method comprising:
providing a first preliminary substrate, wherein the first preliminary substrate includes:
a first base layer,
a display element layer including a light-emitting element disposed on the first base layer,
a light control layer including a division pattern disposed on the display element layer and having an opening in the light control layer, and
a light control part disposed in the opening;
forming a barrier layer on the light control part;
forming a refraction compensation layer on the barrier layer;
forming a thin film layer including a hydrophobic material on the refraction compensation layer to obtain a first substrate;
providing a second substrate including a second base layer;
depositing filling material on a surface of the second substrate; and
bonding the first substrate to the second substrate.

13. The method of claim 12, wherein forming the thin film layer comprises:
depositing aluminum oxide on the refraction compensation layer using atomic layer deposition.

14. The method of claim 13, wherein:
the thin film layer is formed to a thickness of about 0.01 μm to about 2 μm, inclusive.

15. The method of claim 12, wherein forming the thin film layer comprises:
forming a preliminary thin film layer including silicon oxide or silicon nitride on the refraction compensation layer using chemical vapor deposition; and
forming protrusions on the preliminary thin film layer by using a plasma treatment process.

16. The method of claim 12, wherein depositing the filling material comprises:
ejecting the filling material onto the first preliminary substrate, wherein the filling material are spaced apart from each other at a predetermined interval.

17. The method of claim 12, wherein bonding the first substrate and the deposited surface of the second substrate comprises:
positioning the thin film layer to contact the filling material.

18. The method of claim 17, wherein the filling material comprise:
a hydrophilic material, and
the thin film layer is repulsive to the filling material.

19. An electronic device comprising:
a display device including a first substrate, wherein the first substrate includes:
a first base layer,
a display element layer including a light-emitting element disposed on the first base layer,
a light control layer including a division pattern disposed on the display element layer and having an opening in the light control layer,
a light control part disposed in the opening, and
a functional layer disposed on the light control part,
a second substrate disposed on the first substrate and including a second base layer, and
a filling layer disposed between the first substrate and the second substrate,
wherein the functional layer includes a barrier layer, a refraction compensation layer disposed on the barrier layer, and a thin film layer disposed on the refraction compensation layer, and
wherein the thin film layer has a hydrophobic surface facing the second substrate;
a window disposed on the display device;
a case housing the display device; and
an electronic module electrically connected to the display device.

20. The electronic device of claim 19, wherein:
the barrier layer includes silicon nitride,
the refraction compensation layer includes silicon oxide, and
the thin film layer includes aluminum oxide and is in direct contact with the filling layer.
